(19) United States
(12) Patent Application Publication
(10) Pub. No.: US 2019/0094640 A1
(43) Pub. Date: Mar. 28, 2019

(54) ARRAY SUBSTRATE, LIQUID CRYSTAL DISPLAY PANEL, AND DISPLAY DEVICE

(71) Applicants: BOE Technology Group Co., Ltd., Beijing (CN); Hefei BOE Display Technology Co., Ltd., Hefei (CN)

(72) Inventors: Yizhan HAN, Beijing (CN); Zhonghou WU, Beijing (CN); Liugang ZHOU, Beijing (CN); Shou LI, Beijing (CN); Jianwei SUN, Beijing (CN); Yulong XIONG, Beijing (CN); Tao LI, Beijing (CN)

(21) Appl. No.: 16/019,985

(22) Filed: Jun. 27, 2018

(30) Foreign Application Priority Data
Sep. 22, 2017 (CN) 201710867409.7

(51) Int. Cl. G02F 1/1362; H01L 27/12; G02F 1/1343; G02F 1/1368

(52) U.S. Cl. CPC G02F 1/136286; H01L 27/124; H01L 27/1255; G02F 1/134363; G09G 3/3648; G02F 1/13439; G09G 2320/0247; G09G 2320/0219; G02F 1/1368

(57) ABSTRACT

The disclosure provides an array substrate, a liquid crystal display panel, and a display device. The array substrate according to the disclosure includes: an underlying substrate, and a plurality of scan lines and a plurality of data lines, the scan lines and the data lines are arranged to intersect with each other on the underlying substrate, wherein at least one of the scan lines is connected with a capacitor for adjusting common electrode voltage, and the capacitor has one end connected with one of the scan lines, and the other end connected with the common electrode voltage.

### CROSS-REFERENCE TO RELATED APPLICATION

This application claims priority of Chinese Patent Application No. 201710867409.7, filed on Sep. 22, 2017, which is hereby incorporated by reference in its entirety.

### FIELD

The present disclosure relates to the field of display technology, and particularly to an array substrate, a liquid crystal display panel, and a display device.

### BACKGROUND

A liquid crystal display panel is an important component in a Liquid Crystal Display (LCD), and generally includes an array substrate and a color filter substrate arranged opposite to each other, and liquid crystal molecules filled between the array substrate and the color filter substrate. The liquid crystal display panel controls the orientation of the liquid crystal molecules through an electric field to have the transmittivity of the liquid crystal display panel changed to thereby perform a display function.

### SUMMARY

An embodiment of the disclosure provides an array substrate including: an underlying substrate, and a plurality of scan lines and a plurality of data lines, the plurality of scan lines and the plurality of data lines are arranged to intersect with each other on the underlying substrate, wherein at least one of the scan lines is connected with a capacitor for adjusting common electrode voltage, and the capacitor has one end connected with one of the scan lines, and the other end connected with the common electrode voltage.

Optionally, each of the plurality of scan line is connected with the capacitor.

Optionally, the capacitor is arranged in an edge area of the array substrate.

Optionally, the capacitor includes a first electrode and a second electrode; the first electrode is one end of the capacitor connected with the scan line, and the second electrode is one end of the capacitor connected with the common electrode voltage; and projections of the first electrode and the second electrode onto the underlying substrate overlap with each other.

Optionally, the array substrate further includes: an array of thin film transistors connected with the plurality of scan lines and the plurality of data lines, and pixel electrodes connected with drains of the thin film transistors; and the first electrode is arranged at a layer same as a layer on which gates of the thin film transistors, the drains of the thin film transistors, or the pixel electrodes are arranged.

Optionally, the array substrate further includes: an array of thin film transistors connected with the plurality of scan lines and the plurality of data lines, and pixel electrodes connected with drains of the thin film transistors; and the second electrode is arranged at a layer same as a layer on which gates of the thin film transistors, the drains of the thin film transistors, or the pixel electrodes are arranged.

Optionally, the array substrate further includes: an array of thin film transistors connected with the plurality of scan lines and the plurality of data lines, pixel electrodes connected with drains of the thin film transistors, a common electrode corresponding to the pixel electrodes, and a common electrode line connected with the common electrode voltage; and the common electrode and/or the common electrode line is reused as the second electrodes.

Optionally, the common electrode is arranged between gates of the thin film transistors and the underlying substrate, the common electrode line is arranged at a layer same as a layer on which the gates of the thin film transistors are arranged, and the first electrode is arranged at a layer same as the drains of the thin film transistors, or the pixel electrodes are arranged.

An embodiment of the disclosure further provides a liquid crystal display panel including the array substrate according to any one of the embodiments above of the disclosure.

An embodiment of the disclosure further provides a display device including the liquid crystal display panel according to any one of the embodiments above of the disclosure.

### BRIEF DESCRIPTION OF THE DRAWINGS

FIG. 1 is an equivalent circuit diagram of a liquid crystal display panel according to an embodiment of the disclosure.

FIG. 2 is a waveform diagram of varying voltage across liquid crystal molecules of a pixel in the liquid crystal display panel according to the embodiment of the disclosure in a charging stage and a holding stage.

FIG. 3 is a schematic structural diagram of an array substrate according to some embodiments of the disclosure.

FIG. 4 is a schematic structural diagram of an array substrate according to embodiments of the disclosure.

FIG. 5 is a schematic structural diagram of an array substrate according to other embodiments of the disclosure.

FIG. 6 is a schematic structural diagram of an array substrate according to embodiments of the disclosure.

FIG. 7 is a schematic structural diagram of an array substrate according to some embodiments of the disclosure.

FIG. 8 is a schematic structural diagram of an array substrate according to a further some embodiments of the disclosure.

FIG. 9A to FIG. 9E are schematic flow charts of a process of fabricating an array substrate according to an embodiment of the disclosure.

### DETAILED DESCRIPTION OF THE EMBODIMENTS

In the liquid crystal display panel, the electric field for controlling the liquid crystal molecules depends upon the difference in voltage (or pixel voltage) between a pixel electrode and a common electrode, but when a gate signal is disabled, there may be a deviation of feed-through voltage (ΔVₚ) (i.e., a feed-through effect) before and after the voltage at the pixel electrode jumps due to existence of a parasitic capacitor.

The feed-through voltage ΔVₚ of the pixel can be expressed in Equation (1) of:

$$Δ {V}_{p} = \frac{{C}_{gd}}{{C}_{gd} + {C}_{lc} + {C}_{st}} * ( {V}_{gh} - {V}_{gl} ) ; \qquad ( 1 )$$

where ΔVₚ represents the feed-through voltage, C_{gd} represents coupling capacitor between the gate and the drain, C_{lc} represents a liquid crystal capacitor, Cₛₜ represents a storage capacitor, V_{gh} represents high voltage (referred to as on-voltage) on a gate line, and V_{gl} represents low voltage (referred to as off-voltage) on the gate line.

As well known, there may be a lack of balance due to the feed-through voltage ΔVₚ when the polarity of the pixel voltage is inverted, so that there may be some error of a grayscale voltage reference for respective pixels, thus resulting in a human-eye observable flickering segment of an image being displayed, which would degrade the display quality of the liquid crystal display panel.

In view of this, it is highly desirable for those skilled in the art to address the technical problem of how to alleviate or eliminate the feed-through voltage so as to alleviate the flickering segment of the image being displayed, to thereby improve the display quality of the liquid crystal display panel.

Embodiments of the disclosure provide an array substrate, a liquid crystal display panel, and a display device so as to alleviate or eliminate feed-through voltage so as to alleviate a flickering segment of an image being displayed, to thereby improve the display quality of the liquid crystal display panel.

The technical solutions according to the embodiments of the disclosure will be described below clearly and fully with reference to the drawings in the embodiments of the disclosure, and apparently the embodiments to be described are only a part but not all of the embodiments of the disclosure. Based upon the embodiments here of the disclosure, all the other embodiments which can occur to those ordinarily skilled in the art without any inventive effort shall fall into the scope of the disclosure.

It shall be noted the thicknesses and shapes of respective layers in the drawings are not intended to reflect any real proportion, but only intended to illustrate the disclosure of the disclosure.

Referring to FIG. 1 to FIG. 8, an array substrate according to an embodiment of the disclosure includes: an underlying substrate 11, and a plurality of scan lines 12 and a plurality of data lines 13, which are arranged to intersect with each other on the underlying substrate 11, where at least one of the scan lines 12 is connected with a capacitor 14 for adjusting common electrode voltage V_{com}, and the capacitor 14 has one end connected with one of the scan lines, and the other end connected with the common electrode voltage V_{com}.

In an optional implementation, the capacitor 14 is arranged in an edge area of the array substrate, and for example, the capacitor 14 is arranged in the left or right edge area of the array substrate.

Since the capacitor for adjusting the common electrode voltage is arranged in the edge area of the array substrate, the aperture ratio of the liquid crystal display panel will not be affected.

In an optional implementation, as illustrated in FIG. 1, each scan line 12 is connected with a capacitor 14 (denoted as C_{gc} in a dotted box as illustrated in FIG. 1), so that the difference in voltage between a pixel electrode and a common electrode will substantially remain unvaried while data are being displayed at any pixel on a liquid crystal display panel, and thus feed-through voltage can be eliminated as much as possible to thereby alleviate a flickering segment of an image being displayed, so as to improve the display quality of the liquid crystal display panel. FIG. 1 illustrates an equivalent circuit diagram of the liquid crystal display panel including the array substrate, and a storage capacitor Cₛₜ in FIG. 1 has one end connected with the common electrode voltage V_{com}, but the embodiment of the disclosure will not be limited thereto, and for example, the storage capacitor Cₛₜ can alternatively have one end connected with the next scan line. The storage capacitor Cₛₜ is known in the related art, so a repeated description thereof will be omitted here.

In an optional implementation, the sizes and shapes of the respective capacitors 14 are totally the same for the sake of convenient fabrication thereof.

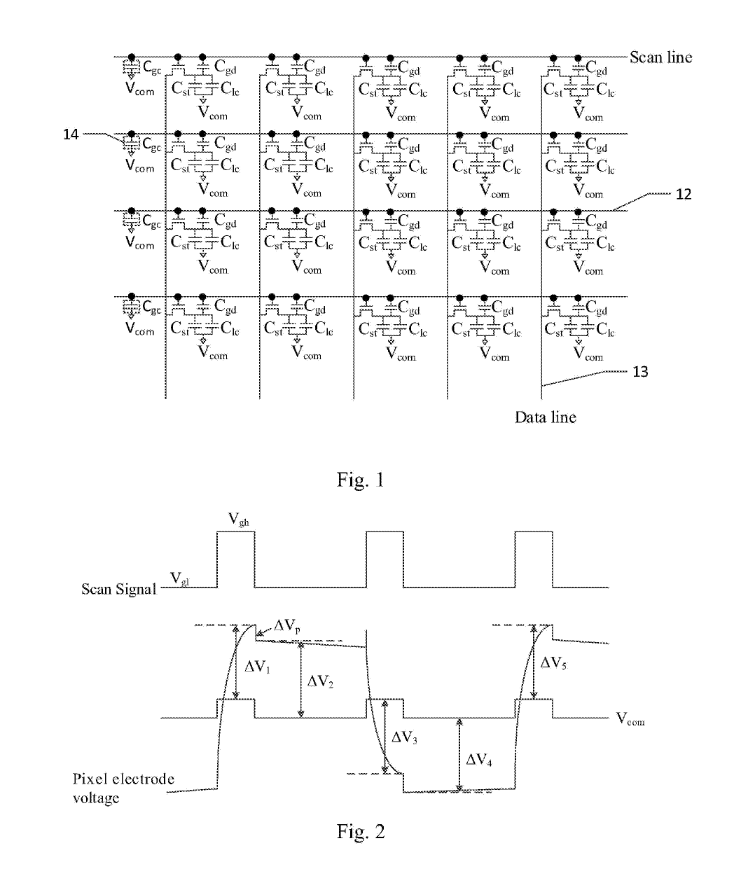

After the capacitors 14 are arranged on the array substrate, FIG. 2 illustrates varying voltage across liquid crystal molecules of a pixel in the liquid crystal display panel including the array substrate in a charging stage and a holding stage. As illustrated in FIG. 2, from a moment of switching on a thin film transistor to a moment of switching off the thin film transistor, the voltage at the pixel electrode rises and drops with rising and dropping gate voltage due to the feed-through effect to thereby adjust the capacitor for the common electrode voltage so that the common electrode voltage rises and drops as the gate voltage on the scan line connected with the capacitor rises and drops, so the difference in voltage between the pixel electrode of the pixel on the liquid crystal display panel, and the common electrode will substantially remain unvaried while data are being displayed at the pixel, that is, ΔV₁=ΔV₂=ΔV₃=ΔV₄=ΔV₅, and in this way, the feed-through voltage can be alleviated or eliminated to thereby alleviate a flickering segment of an image being displayed, so as to improve the display quality of the liquid crystal display panel.

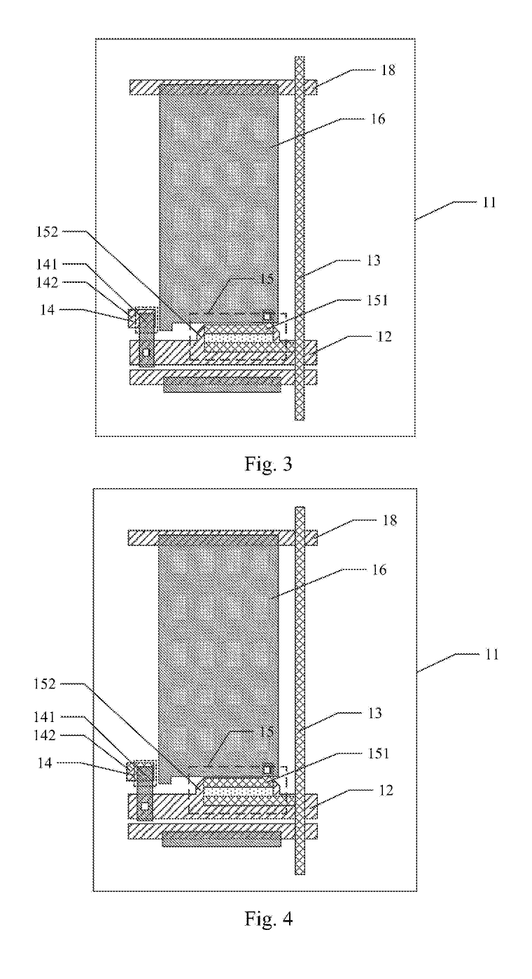

In an optional implementation, as illustrated in FIG. 3 to FIG. 8, the capacitor 14 includes a first electrode 141 and a second electrode 142, where the first electrode 141 is the end of the capacitor 14 connected with the scan line 12, and the second electrode 142 is the end of the capacitor 14 connected with the common electrode voltage V_{com}; and projections of the first electrode 141 and the second electrode 142 onto the underlying substrate 11 overlap with each other, so that a vertical capacitor can be formed to thereby adjust the common electrode voltage V_{com} so that the difference in voltage between the pixel electrode and the common electrode substantially remains unvaried, so the feed-through voltage can be alleviated to thereby alleviate a flickering segment of an image being displayed, so as to improve the display quality of the liquid crystal display panel. Here the overlapping area between the first electrode 141 and the second electrode 142 can be set as needed in reality, dependent upon the feed-through voltage ΔVₚ, the distance between the first electrode 141 and the second electrode 142, and other factors.

As illustrated in FIG. 3 to FIG. 8, the array substrate typically further includes an array of thin film transistors 15 (denoted in dotted boxes as illustrated) connected with the plurality of scan lines 12, and the plurality of data lines 13, and pixel electrodes 16 connected with drains 151 of the thin film transistors.

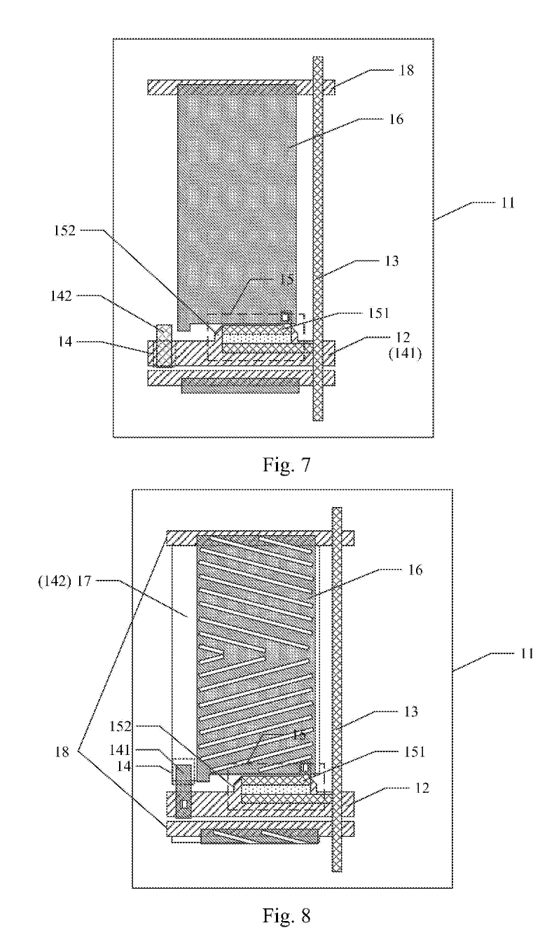

Referring to FIG. 8, in order to fabricate the liquid crystal display panel in the ADS mode, the array substrate generally further includes: a common electrode 17 corresponding to the pixel electrodes 16, and a common electrode line 18 connected with the common electrode voltage V_{com}.

The first electrode 141 and the second electrode 142 in the capacitor 14 above can be arranged in a number of implementations, which will be described below by way of an example with reference to the drawings.

Referring to FIG. 3, in the array substrate according to some embodiments of the disclosure, the first electrode 141 is arranged at the same layer as the pixel electrode 16, and the second electrode 142 is arranged at the same layer as the gate 152 of the thin film transistor 15. For example, the first electrode 141 can be connected with the scan line 12 through a through-hole, and the second electrodes 142 of the respective capacitors 14 can be firstly connected onto a line, and then the line can be further connected with the common electrode voltage V_{com}, where projections of the line and the data lines 13 onto the underlying substrate 11 can be parallel to each other, for example. Of course, the second electrodes 142 of the respective capacitors 14 can alternatively be connected respectively with the common electrode voltage V_{com}, although the embodiment of the disclosure will not be limited thereto.

Referring to FIG. 4, in the array substrate according to some embodiments of the disclosure, the first electrode 141 is arranged at the same layer as the pixel electrode 16, and the second electrode 142 is arranged at the same layer as the drain 151 of the thin film transistor 15. For example, the first electrode 141 can be connected with the scan line 12 through a through-hole, and the second electrodes 142 of the respective capacitors 14 can be firstly connected onto a line, and then the line can be further connected with the common electrode voltage V_{com}, where projections of the line and the data lines 13 onto the underlying substrate 11 can be parallel to each other, for example. Of course, the second electrodes 142 of the respective capacitors 14 can alternatively be connected respectively with the common electrode voltage V_{com}, although the embodiment of the disclosure will not be limited thereto.

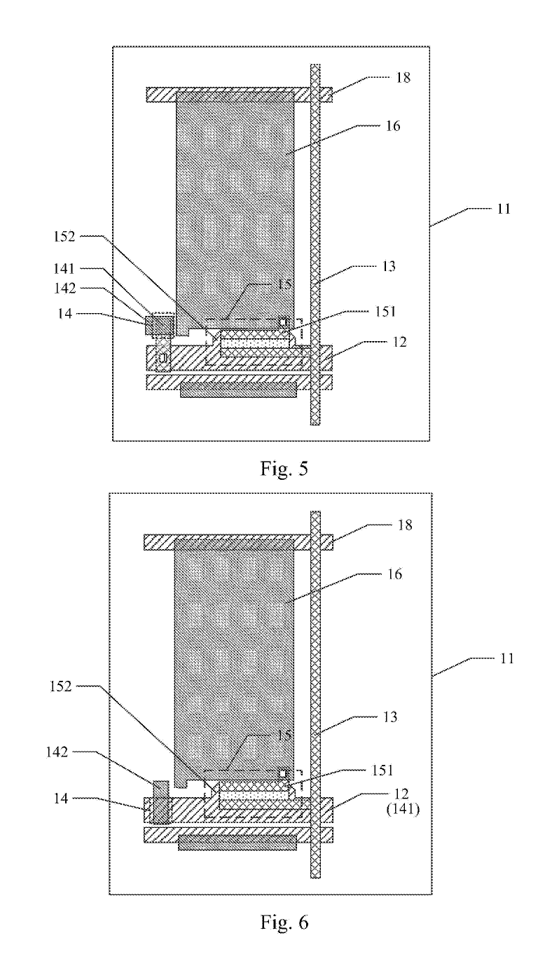

Referring to FIG. 5, in the array substrate according to some embodiments of the disclosure, the first electrode 141 is arranged at the same layer as the drain 151 of the thin film transistor 15, and the second electrode 142 is arranged at the same layer as the pixel electrode 16. For example, the first electrode 141 can be connected with the scan line 12 through a through-hole, and the second electrodes 142 of the respective capacitors 14 can be firstly connected onto a line, and then the line can be further connected with the common electrode voltage V_{com}, where projections of the line and the data lines 13 onto the underlying substrate 11 can be parallel to each other, for example. Of course, the second electrodes 142 of the respective capacitors 14 can alternatively be connected respectively with the common electrode voltage V_{com}, although the embodiment of the disclosure will not be limited thereto.

Referring to FIG. 6, in the array substrate according to some embodiments of the disclosure, the first electrode 141 is arranged at the same layer as the gate 152 of the thin film transistor 15, and the second electrode 142 is arranged at the same layer as the pixel electrode 16. For example, the scan line 12 can be reused for the first electrode 141, or the first electrode 141 can be arranged on the scan line 12, and the second electrodes 142 of the respective capacitors 14 can be firstly connected onto a line, and then the line can be further connected with the common electrode voltage V_{com}, where projections of the line and the data lines 13 onto the underlying substrate 11 can be parallel to each other, for example. Of course, the second electrodes 142 of the respective capacitors 14 can alternatively be connected respectively with the common electrode voltage V_{com}, although the embodiment of the disclosure will not be limited thereto.

Referring to FIG. 7, in the array substrate according to some embodiments of the disclosure, the first electrode 141 is arranged at the same layer as the gate 152 of the thin film transistor 15, and the second electrode 142 is arranged at the same layer as the drain 151 of the thin film transistor 15. For example, the scan line 12 can be reused for the first electrode 141, or the first electrode 141 can be arranged on the scan line 12, and the second electrodes 142 of the respective capacitors 14 can be firstly connected onto a line, and then the line can be further connected with the common electrode voltage V_{com}, where projections of the line and the data lines 13 onto the underlying substrate 11 can be parallel to each other, for example. Of course, the second electrodes 142 of the respective capacitors 14 can alternatively be connected respectively with the common electrode voltage V_{com}, although the embodiment of the disclosure will not be limited thereto.

Referring to FIG. 8, an array substrate according to some embodiments of the disclosure is applied to a liquid crystal display panel in the ADS mode, and the array substrate includes: a common electrode 17 corresponding to the pixel electrodes 16, and a common electrode line 18 connected with the common electrode voltage V_{com}, where the common electrode 17 is reused as the second electrodes 142.

Of course, the common electrode 17 may alternatively be not reused as the second electrodes 142, but the common electrode line 18 may be reused as the second electrodes 142, or the common electrode 17 and the common electrode line 18 may be reused as the second electrodes 142, although the embodiment of the disclosure will not be limited thereto.

In an optional implementation, the common electrode 17 is arranged between the gates 152 of the thin film transistors 15 and the underlying substrate 11, the common electrode line 18 is arranged at the same layer as the gates 152 of the thin film transistors 15, and the first electrodes 141 may be arranged at the same layer as the pixel electrodes 16 as illustrated in FIG. 8; or the first electrode 141 may be arranged as the same layer as the drains 151 of the thin film transistors 15, although the embodiment of the disclosure will not be limited thereto.

In another optional implementation, the common electrode 17 is arranged above the pixel electrodes 16, the common electrode 17 is reused as the second electrodes 142, and the first electrodes 141 may be arranged at the same layer as the pixel electrodes 16, or the first electrodes 141 may be arranged at the same layer as the gates 152 of the thin film transistors 15, or the first electrodes 141 may be arranged at the same layer as the drains 151 of the thin film transistors 15, although the embodiment of the disclosure will not be limited thereto.

The same-layer arrangement or reused-layer arrangement according to any one of aforementioned embodiments can simplify the process for fabricating the array substrate.

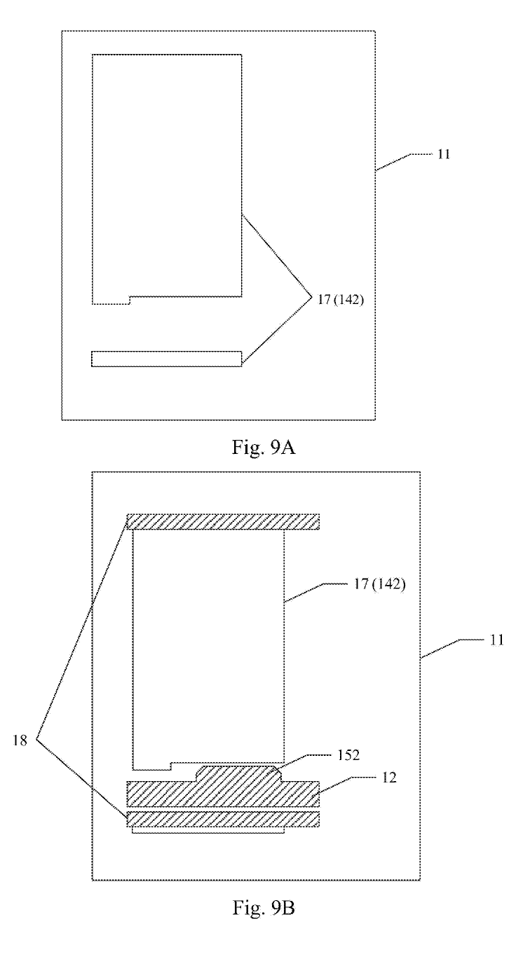

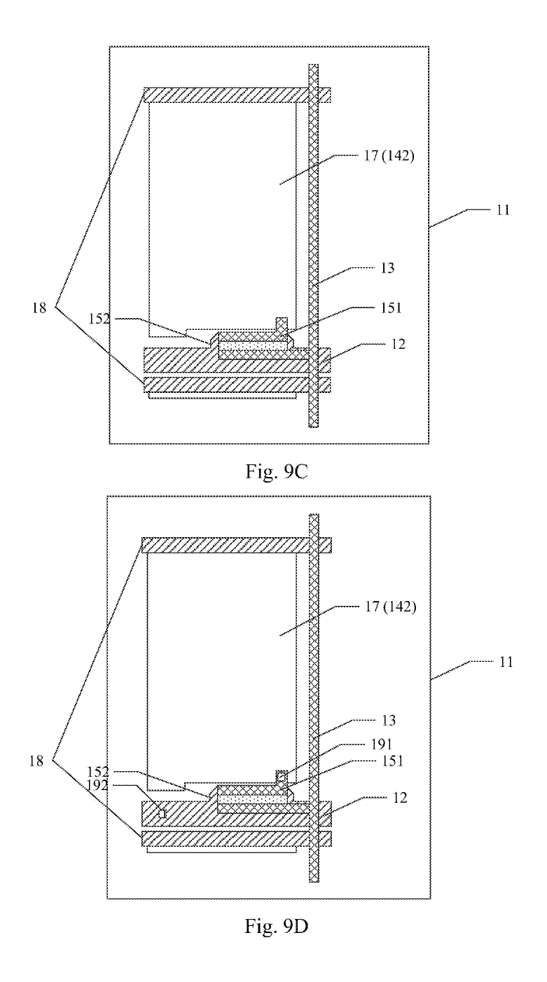

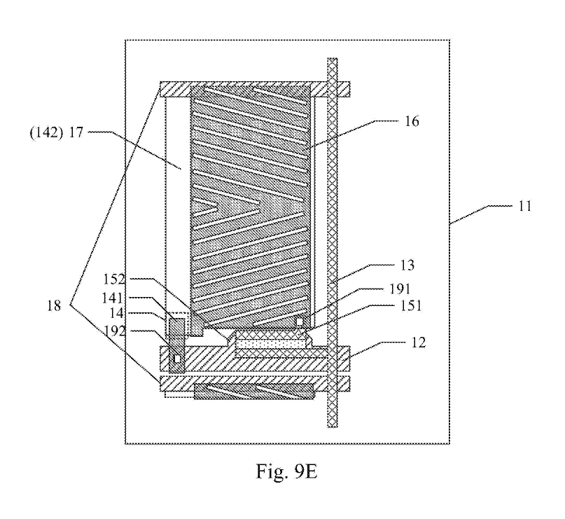

A flow of a process for fabricating the array substrate according to embodiments of the disclosure will be described below in details with reference to FIG. 9A to FIG. 9E.

Referring to FIG. 9A, the first step is to form the common electrode 17 on the underlying substrate in a first patterning processes, where the common electrode 17 is reused as the second electrodes 142.

Referring to FIG. 9B, the second step is to form the gates 152 of the thin film transistors, the scan lines 12, and the common electrode line 18 in a second patterning process, where the common electrode line 18 is connected with the common electrode 17, the gates 152 of the think film transistors do not come into contact with the common electrode 17, and for example, the materials of the gates 152, the scan lines 12, and the common electrode line 18 can be Mo/Al/Mo.

Referring to FIG. 9C, the third step is to form a gate insulation layer on the gates 152, the scan lines 12, and the common electrode line 18, and to form an active layer, a source, the drain 151, and the data lines 13 on the gate insulation layers in a third patterning process, where the source is connected with the data lines 13, and for example, the materials of the source, the drain 151, and the data lines 13 can be Mo/Al/Mo.

Referring to FIG. 9D, the fourth step is to form a passivation layer on the source, the drain 151, and the data lines 13, and to form the first through-hole 191 and the second through-hole 192 in a fourth patterning process.

Referring to FIG. 9E, the fifth step is to form the pixel electrode 16 and the first electrode 141 on the passivation layer formed with the first through-hole 191 and the second through-hole 192 in a fifth patterning process where the pixel electrode 16 is connected with the drain 151 of the think film transistor through the first through-hole 191, the first electrode 141 is connected with the scan line 12 through the second through-hole 192, and the projections of the first electrode 141 and the second electrode 142 onto the underlying substrate 11 overlap with each other (as denoted in a dotted box as illustrated in FIG. 9E), thus forming the capacitors 14 for adjusting the common electrode voltage.

Based upon the same inventive idea, embodiments of the disclosure further provide a liquid crystal display panel including the array substrate according to any one of the embodiments above of the disclosure.

Based upon the same inventive idea, embodiments of the disclosure further provide a display device including the liquid crystal display panel according to any one of the embodiments above of the disclosure. The display device can be a mobile phone, a tablet computer, a TV set, a monitor, a notebook computer, a digital photo frame, a navigator, or any other product or component with a display function.

In summary, in the technical solutions according to embodiments of the disclosure, the array substrate includes: an underlying substrate, and a plurality of scan lines and a plurality of data lines, which are arranged to intersect with each other on the underlying substrate, where at least one of the scan lines is connected with a capacitor for adjusting common electrode voltage, and the capacitor has one end connected with one of the scan lines, and the other end connected with the common electrode voltage. Since the capacitor for adjusting the common electrode voltage is connected on at least one of the scan lines, from a moment of switching on a thin film transistor to a moment of switching off the thin film transistor, the voltage at a pixel electrode rises and drops with rising and dropping gate voltage due to the feed-through effect to thereby adjust the capacitor for the common electrode voltage so that the common electrode voltage rises and drops as the gate voltage on the scan line connected with the capacitor rises and drops, so the difference in voltage between the pixel electrode of the pixel on the liquid crystal display panel, and the common electrode will substantially remain unvaried while data are being displayed at the pixel, connected with the capacitor, on the scan line, and in this way, the feed-through voltage can be alleviated or eliminated to thereby alleviate a flickering segment of an image being displayed, so as to improve the display quality of the liquid crystal display panel.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. An array substrate, comprising: an underlying substrate, and a plurality of scan lines and a plurality of data lines, the plurality of scan lines and the plurality of data lines are arranged to intersect with each other on the underlying substrate, wherein at least one of the plurality of scan lines is connected with a capacitor for adjusting common electrode voltage, and the capacitor has one end connected with one of the plurality of scan lines, and the other end is connected with the common electrode voltage.

2. The array substrate according to claim 1, wherein each of the plurality of scan lines is connected with the capacitor.

3. The array substrate according to claim 1, wherein the capacitor is arranged in an edge area of the array substrate.

4. The array substrate according to claim 1, wherein the capacitor comprises a first electrode and a second electrode; the first electrode is the one end of the capacitor connected with the at least one of scan lines, and the second electrode is the other end of the capacitor connected with the common electrode voltage; and projections of the first electrode and the second electrode onto the underlying substrate overlap with each other.

5. The array substrate according to claim 2, wherein the capacitor comprises a first electrode and a second electrode; the first electrode is the one end of the capacitor connected with the at least one of scan lines, and the second electrode is the other end of the capacitor connected with the common electrode voltage; and projections of the first electrode and the second electrode onto the underlying substrate overlap with each other.

6. The array substrate according to claim 3, wherein the capacitor comprises a first electrode and a second electrode; the first electrode is the one end of the capacitor connected with the at least one of scan lines, and the second electrode is the other end of the capacitor connected with the common electrode voltage; and projections of the first electrode and the second electrode onto the underlying substrate overlap with each other.

7. The array substrate according to claim 4, further comprises: an array of thin film transistors connected with the plurality of scan lines and the plurality of data lines, and pixel electrodes connected with drains of the thin film transistors; and the first electrode is arranged at a layer same as a layer on which gates of the thin film transistors, the drains of the thin film transistors, or the pixel electrodes are arranged.

8. The array substrate according to claim 4, further comprises: an array of thin film transistors connected with the plurality of scan lines and the plurality of data lines, and pixel electrodes connected with drains of the thin film transistors; and the second electrode is arranged at a layer same as a layer on which gates of the thin film transistors, the drains of the thin film transistors, or the pixel electrodes are arranged.

9. The array substrate according to claim 4, further comprises: an array of thin film transistors connected with the plurality of scan lines and the plurality of data lines, pixel electrodes connected with drains of the thin film transistors, a common electrode corresponding to the pixel electrodes, and a common electrode line connected with the common electrode voltage; and the common electrode and/or the common electrode line is reused as the second electrode.

10. The array substrate according to claim 9, wherein the common electrode is arranged between gates of the thin film transistors and the underlying substrate, the common electrode line is arranged at a same layer same as a layer on which the gates of the thin film transistors are arranged, and the first electrode is arranged at a layer same as a layer on which the drains of the thin film transistors, or the pixel electrodes are arranged.

11. A liquid crystal display panel, comprising the array substrate according to claim 1.

12. A display device, comprising the liquid crystal display panel according to claim 11.
